(19) United States
(12) Patent Application Publication
(10) Pub. No.: US 2010/0233590 A1
(43) Pub. Date: Sep. 16, 2010

(54) Method for Manufacturing Photo Mask Using Fluorescence Layer

(75) Inventor: Jin Ho Ryu, Cheongju-si (KR)

Correspondence Address: MARSHALL, GERSTEIN & BORUN LLP, 233 SOUTH WACKER DRIVE, 6300 WILLIS TOWER, CHICAGO, IL, 60606-6357, US

(73) Assignee: HYNIX SEMICONDUCTOR INC., Icheon-si (KR)

(21) Appl. No.: 12/648,047

(22) Filed: Dec. 28, 2009

(30) Foreign Application Priority Data
Mar. 10, 2009 (KR) 10-2009-0020357

(51) Int. Cl. G03F 1/00

(52) U.S. Cl. 430/5

(57) ABSTRACT

A method for fabricating a photo mask using a fluorescence layer, comprising: forming a fluorescence layer on a frame region of a light-transmitting substrate that defines a main cell region and the frame region; forming a phase-shift layer and a light-shielding layer on the light-transmitting substrate and the fluorescence layer; forming a light-shielding main pattern in the main cell region and a light-shielding frame pattern in the frame region by patterning the light-shielding layer; forming a phase-shift main pattern and a phase-shift frame pattern to expose a portion of a surface of the fluorescence layer on side walls thereof, by etching the phase-shift layer using the light-shielding main pattern and the light-shielding frame pattern as an etch mask; irradiating light from a light source on the light-transmitting substrate and detecting an intensity of fluorescence of a fluorescence layer residue emitted from the exposed surface of the fluorescence layer; and determining under-etch or over-etch using the detected fluorescence intensity as a reference fluorescence intensity.

### CROSS-REFERENCE TO RELATED APPLICATION

Priority to Korean patent application number 10-2009-0020357 filed on Mar. 10, 2009, the entire disclosure of which is incorporated by reference, is claimed.

### BACKGROUND OF THE INVENTION

The invention relates generally to a photo mask and, more particularly, to method for fabricating a photo mask using a fluorescence layer.

A photo mask functions to form a desired pattern on a wafer while light is irradiated on a mask pattern formed on a substrate and selectively transmitted light is transferred onto the wafer. As the photo mask, a binary mask made by forming a light-shielding pattern containing chromium (Cr) on a substrate and having a light-transmitting region for transmitting light therethrough and a light-shielding region for shielding the light is generally used. As pattern sizes become finer with increases in the degree of integration of semiconductor devices, there has been proposed and employed, besides the binary mask, a phase-shift mask using a phase-shift material having a transmittance of several percent and being capable of forming finer patterns.

In some cases, a material to be etched is over-etched in an etch process for forming a target pattern by etching the material to be etched on a mask. There is a problem in that it is difficult to form a desired pattern on the wafer when the etch process is performed excessively. Accordingly, an end-point detection system is introduced to control the etch process. The etch end-point detection system is classified depending on a detection source into an optical emission spectroscope (OES), an interferometer, an end-point detector using radial frequency, an end-point detector using an optical filter, a monochrometer, and a spectroscope using charge coupled device (CCD).

A method of detecting an etch end point using this etch end-point detection system is a method of confirming a degree of the reaction and progress of the etch process by determining production or reduction of a specific material from information of light generated and emitted by a plasma reaction. It may be difficult to precisely measure sensitivity in the method of detecting the etch end point due to an analysis concentration of the produced component and complexity of the reaction product by abnormal production. There are also a difference in a concentration of the product depending on a pattern density and a design of the mask. Accordingly, it is difficult to monitor the etch end-point detection point when fabricating different kinds of photo masks in small quantities.

### SUMMARY OF THE INVENTION

In one embodiment, a method for fabricating a photo mask using a fluorescence layer comprises: forming a fluorescence layer on a frame region of a light-transmitting substrate that defines a main cell region and the frame region; forming a phase-shift layer and a light-shielding layer on the light-transmitting substrate and the fluorescence layer; forming a light-shielding main pattern in the main cell region and a light-shielding frame pattern in the frame region by patterning the light-shielding layer; forming a phase-shift main pattern and a phase-shift frame pattern to expose a portion of a surface of the fluorescence layer on side walls thereof, by etching the phase-shift layer using the light-shielding main pattern and the light-shielding frame pattern as an etch mask; irradiating light from a light source on the light-transmitting substrate and detecting an intensity of fluorescence of a fluorescence layer residue emitted from the exposed surface of the fluorescence layer; and determining under-etch or over-etch using the detected fluorescence intensity as a reference fluorescence intensity.

Preferably, the fluorescence layer comprises a material having an excitation wavelength of 340 nm to 400 nm, and preferably contains fluorene or pyrene.

Preferably, detecting the fluorescence intensity comprises: disposing a fluorometer in a front side of the light-transmitting substrate and a light source in a rear side of the light-transmitting substrate; and irradiating the light from the light source on the light-transmitting substrate and detecting the intensity of fluorescence of a fluorescence layer residue emitted from the fluorescence layer with the fluorometer.

Alternatively, detecting of the fluorescence intensity may comprise irradiating ultraviolet light from a ultraviolet lamp on the light-transmitting substrate and inspecting the intensity of the emitted fluorescence with a user's eye

Preferably, in determining the under-etch or the over-etch on the basis of the detected fluorescence intensity, etching of the phase-shift layer is determined as the under-etch, wherein etching is performed only to a point not reaching a target etch point, when the intensity of the emitted fluorescence is higher than the reference fluorescence intensity, and etching of the phase-shift layer is determined as the over-etch, wherein etch is performed only to a point not reaching a target etch point, when the intensity of the emitted fluorescence is lower than the reference fluorescence intensity or the intensity of fluorescence of a fluorescence layer residue is not detected.

In another embodiment, a method for fabricating a photo mask using a fluorescence layer comprises: forming a trench in a frame region of a light-transmitting substrate that defines a main cell region and the frame region; partially burying the trench with a fluorescence layer; completely burying the trench by forming a light-shielding layer on the fluorescence layer; forming a mask layer and a resist layer on the light-shielding layer and the light-transmitting substrate; forming a resist pattern to expose a portion of a surface of the mask layer by patterning the resist layer; and forming a mask main pattern in the main cell region and a mask frame region in the frame region by an etch process using the resist pattern as an etch mask, wherein the mask frame pattern is formed while restricting exposure of the fluorescence layer by monitoring an intensity of fluorescence in the frame region.

Preferably, in monitoring of the fluorescence intensity, a fluorometer is disposed in a front side of the light-transmitting substrate, setting up a point where the fluorescence intensity of the fluorescence layer is increased as an over-etch point, and monitoring the frame region.

### BRIEF DESCRIPTION OF THE DRAWINGS

FIGS. 1 through 6 illustrate a method for fabricating a photo mask using a fluorescence layer in accordance with an embodiment of the invention.

FIGS. 7A and 7B illustrate detection according to an etch result.

FIGS. 8 through 11 illustrate a method for fabricating a photo mask using a fluorescence layer in accordance with another embodiment of the invention.

### DESCRIPTION OF SPECIFIC EMBODIMENTS

Hereinafter, a method for fabricating contacts in a semiconductor device in accordance with the invention is described in detail with reference to the accompanying drawings.

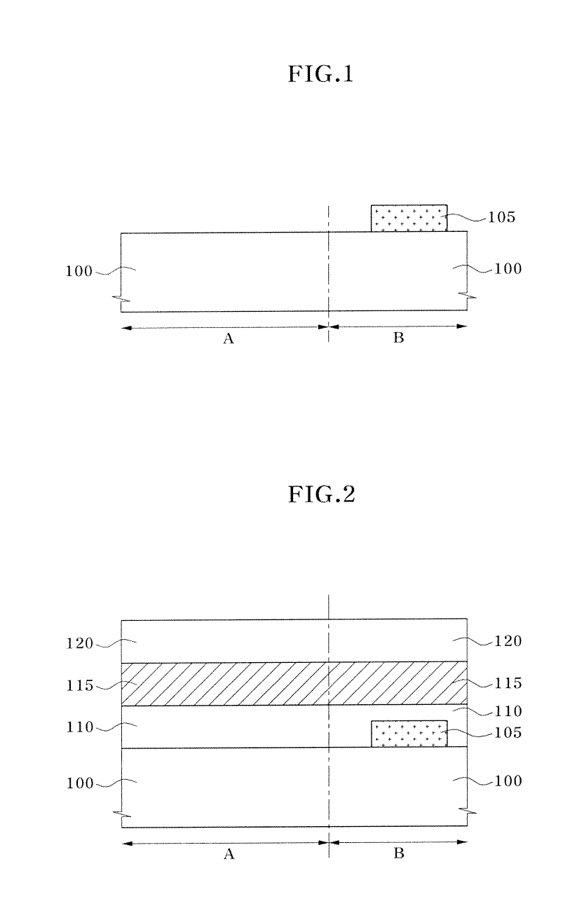

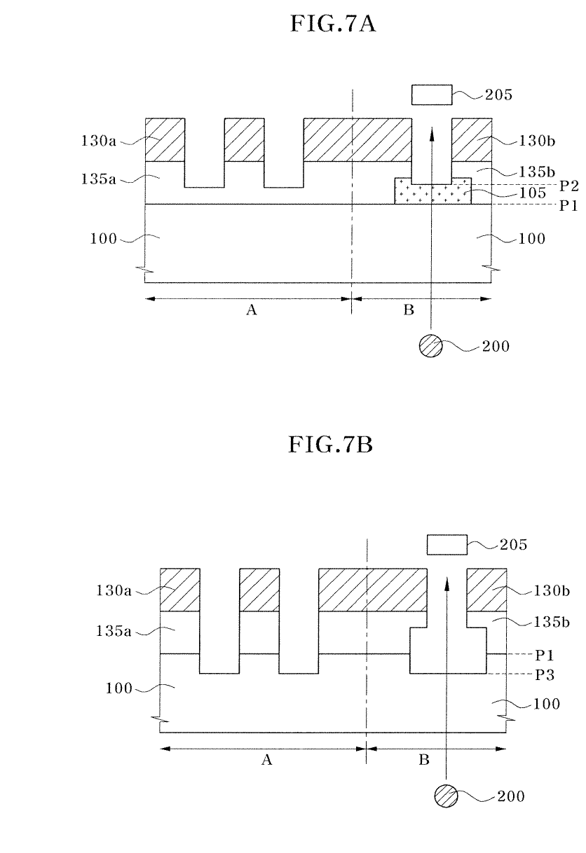

FIGS. 1 through 6 illustrate a method for fabricating a photo mask using a fluorescence layer in accordance with an embodiment of the invention. FIGS. 7A and 7B illustrate detection according to an etch result.

Referring to FIG. 1, a light-transmitting substrate 100 is prepared. The light-transmitting substrate 100 preferably contains quartz and comprises a transparent material allowing transmission of light. The substrate 100 defines a main cell region A in which main patterns are disposed and a frame region B disposed around the main cell region A. Next, a fluorescence layer 105 is formed on the frame region B of the light-transmitting substrate 100. The fluorescence layer 105 preferably comprises a material containing fluorene or pyrene and having an excitation wavelength of 340 nm to 400 nm. In this case, the fluorescence layer 105 preferably is formed on the frame region B, which does not affect the main patterns to be subsequently formed, highly preferably by chemical vapor deposition (CVD).

Referring to FIG. 2, a phase-shift layer 110 is formed on an entire surface of the fluorescence layer 105 and the light-transmitting substrate 100. The phase-shift layer 110 formed on the fluorescence layer 105 and the light-transmitting substrate 100 comprises a compound containing molybdenum (Mo). The molybdenum-containing compound highly preferably comprises molybdenum silicon oxynitride (MoSiON). A light-shielding layer 115 is successively deposited on the phase-shift layer 110. The light-shielding layer 115 formed on the phase-shift layer 110 shields the light transmitted through the substrate 100 in an exposure process to be subsequently performed. This light-shielding layer 115 can be formed including chromium (Cr). Next, a resist layer 120 is formed on the light-shielding layer 115 to form a blank mask in which the phase-shift layer 110, the light-shielding layer 115, and the resist layer 120 are formed on the light-transmitting substrate 100 in the main cell region A and fluorescence layer 105, the phase-shift layer 110, the light-shielding layer 115, and the resist layer 120 are formed on the light-transmitting substrate 100 in the frame region B.

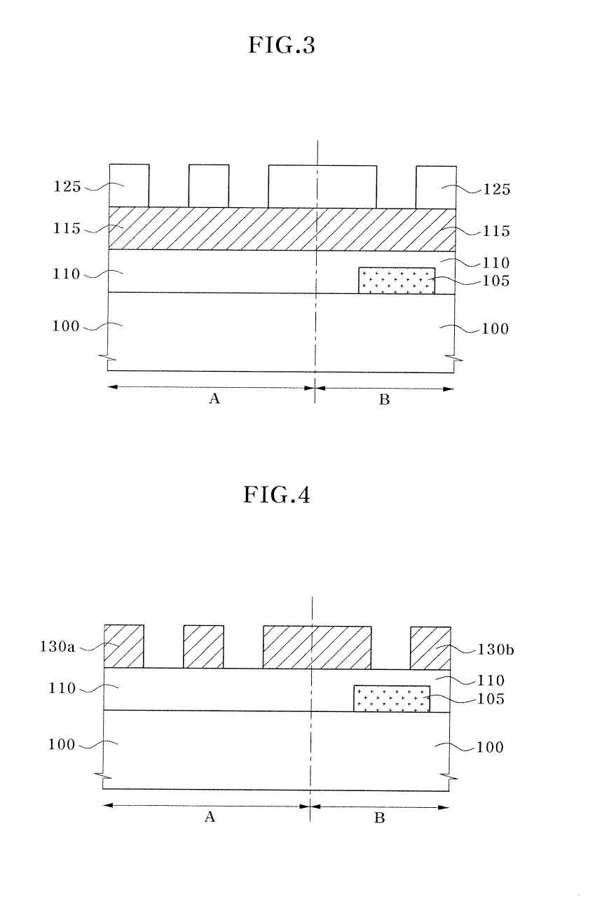

Referring to FIG. 3, a lithography process comprising an exposure process and a development process is performed on the resist layer (120 of FIG. 2) to form a resist pattern 125 that partially exposes a surface of the light-shielding layer 115. Specifically, an exposure process using electron beam equipment preferably is performed on the resist layer 120. Then, a difference in solubility is generated according to a photo-chemical reaction between the portion of the resist layer 120 irradiated with light and the portion of the resist layer 120 not irradiated with light. Next, by performing the development process, some portion of the resist layer 120 is removed by a developing solution and the resist pattern 125 that exposes some portion of the surface of the light-shielding layer 115 is formed.

Referring to FIG. 4, the exposed surface of the light-shielding layer 115 is etched using the resist pattern 125 as an etch mask to form light-shielding pattern 130a, 130b. Here, the light-shielding pattern 130a, 130b includes a light-shielding main pattern 130a formed in the main cell region A and a light-shielding frame pattern 130b formed in the frame region B. A portion of the phase-shift layer 110 thereunder is exposed by the light-shielding main pattern 130a and the light-shielding frame pattern 130b formed in the frame region B. The resist pattern 125 is removed by a strip process.

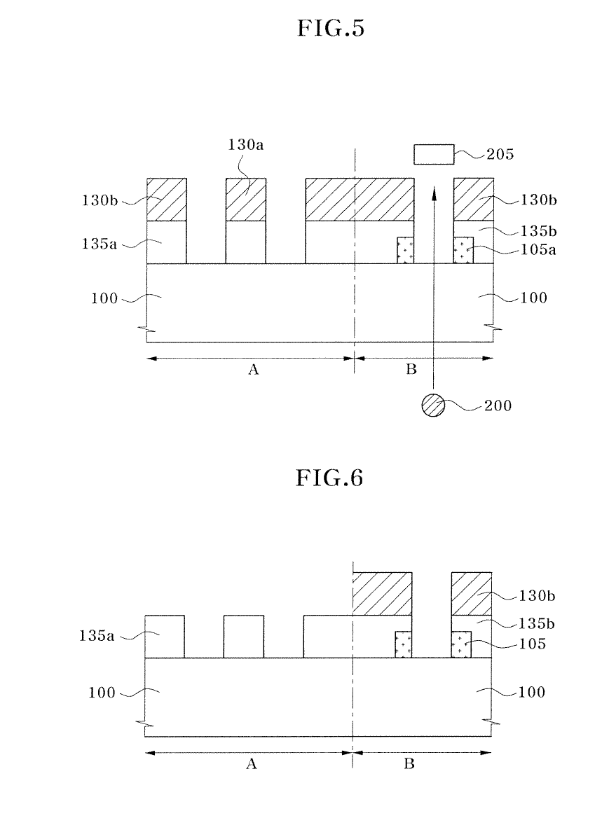

Referring to FIG. 5, an exposed portion of the phase-shift layer (110, see FIG. 4) is etched using the light-shielding main pattern 130a and the light-shielding frame pattern 130b as an etch mask. Then, a phase-shift main pattern 135a is formed in the main cell region A and a phase-shift frame pattern 135b is formed in the frame region B. At this time, the fluorescence layer 105a is partially exposed on side walls of the phase-shift pattern 135b in the frame region B. And, a portion of a surface of the light-transmitting substrate 100 is exposed by the phase-shift main pattern 135a and the phase-shift frame pattern 135b.

Next, light from a light source is irradiated on the light-transmitting substrate 100 to detect a fluorescence intensity of fluorescence material residue. To this end, the light source 200 preferably is disposed in a rear side of the light-transmitting substrate 100 in the frame region B and a fluorometer 205 is disposed in a front side of the light-transmitting substrate 100. Next, the light is irradiated, as indicated by an arrow shown in the drawing figure, in a direction from the rear side of the light-transmitting substrate 100 to the front side and the intensity of the fluorescence emitted from the fluorescence layer 105a of which side surface is partially exposed is detected with the fluorometer 205 disposed in the front side of the light-transmitting substrate 100. The detected fluorescence intensity is varied (higher or lower) as an exposure region of a portion coated with the fluorescence material. It is therefore possible to easily determine the progress of the etch process. Accordingly, the detected fluorescence intensity which emitted from the fluorescence layer 105a becomes a reference fluorescence intensity for determining the progress of the etch process. For the detection of the fluorescence intensity, a method of detecting the fluorescence intensity using the fluorometer 205 preferably is used as described above or, alternatively, a method of irradiating ultraviolet light of 365 nm from an ultraviolet lamp and inspecting the intensity of the emitted fluorescence with a user's eye can be used.

Referring to FIG. 6, when it is deemed that the etch process is normally performed and the phase-shift pattern 135a, 135b fit for the purpose is formed, the light-shielding main pattern 130a in the main cell region A is removed and subsequent processes are performed to thereby complete the mask fabrication process.

Meanwhile, over-etch, in which the etch process is excessively performed, or under-etch, in which the etch process is not performed to reach a target etch point, can be determined by detecting the fluorescence intensity on the basis of the reference determined by detecting the intensity of the fluorescence emitted from the fluorescence layer 105a, of which a side surface is partially exposed, with the fluorometer 205.

As shown in FIG. 7A, in the under-etch, in which the surface of the fluorescence layer 105 is exposed as the etch is performed only to a point P2 which does not reach a target etch point P1, the intensity of the emitted fluorescence is shown higher than the reference fluorescence intensity detected in FIG. 5. Also, as shown in FIG. 7B, in the over-etch, in which the light-transmitting substrate 100 is etched to a predetermined depth P2 and the fluorescence layer is removed as the etch is excessivley performed to a point below the target etch point P1, the intensity of the emitted fluorescence is shown to be lower than the reference fluorescence intensity detected in FIG. 5, or is not detected. Fluorene or pyrene preferably contained in the fluorescence layer has an excitation wavelength of 340 nm to 400 nm, a blue fluorescent light having a wavelength between 450 nm and 500 nm is emitted when a light having an excitation wavelength of 340 nm is used.

Since the intensity F of the emitted fluorescence is proportional to a concentration C of the fluorescence material (F=KC, where K is a proportional factor), the fluorescence intensity is determined depending on a residual amount of the fluorescence material coated by chemical vapor deposition, for example. Accordingly, in the under-etch in which the etch is not performed up to a target etch point, a portion of the surface of the fluorescence layer 105 is exposed and the fluorescence intensity is rapidly increased as compared to the reference fluorescence intensity. As such, it is possible to determine the under-etch on the basis of the rapidly increased fluorescence intensity.

Also, since in the over-etch the fluorescence intensity is shown lower than the reference fluorescence intensity as the fluorescence layer is removed and the light-transmitting substrate 100 is also etched, it is possible to determine the over-etch by comparison of the fluorescence intensity with the reference fluorescence intensity. As such, an etch degree of the phase-shift pattern 135a, 135b is determined from the fluorescence intensity of the fluorescence material residue according to the etch degree by comparing it with the reference fluorescence intensity to control an etch rate of the fluorescence layer and the phase-shift layer.

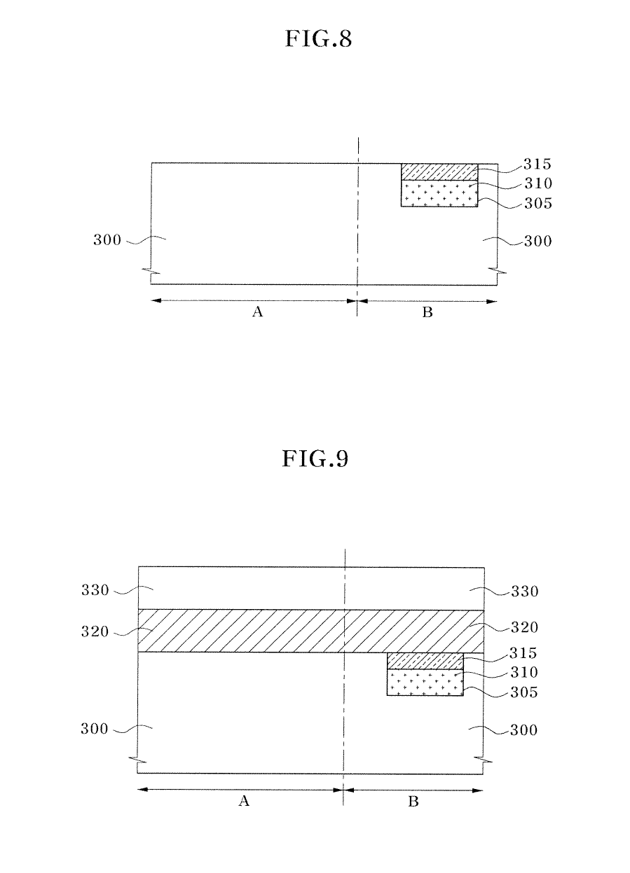

Meanwhile, the etch end point monitoring pattern using a fluorescence layer can be formed using a structure for preventing over-etch. FIGS. 8 through 11 illustrate a method for fabricating a photo mask using a fluorescence layer in accordance with another embodiment of the invention.

Referring to FIG. 8, a fluorescence layer 310 and a light-shielding layer (quencher) 315 are formed on a light-transmitting substrate 300 in a frame region B. Specifically, a trench having 305 having a predetermined depth is formed in the light-transmitting substrate 300 in the frame region B. Successively, the fluorescence layer 310, which partially buries the trench 305, is deposited. The fluorescence layer 310 preferably comprises a material containing fluorene or pyrene and having an excitation wavelength of 340 nm to 400 nm. The fluorescence layer 310 preferably is formed by chemical vapor deposition (CVD) and preferably is deposited to a height that causes a problem such as a mask defect by over-etch of the light-transmitting substrate 300 during a mask fabrication process. Successively, the light-shielding layer 315 is formed on the fluorescence layer 310 to completely bury the trench 305. Next, the light-shielding layer 315 is polished to a height equal to a surface of the light-transmitting substrate 300, preferably by a planarization process, e.g. chemical mechanical polishing. This light-shielding layer 315 preferably comprises a chromium (Cr) layer. The fluorescence layer 310 and the light-shielding layer 315 function as an etch end point monitoring pattern for preventing over-etch of the light-transmitting substrate 300 in subsequent processes.

Referring to FIG. 9, a mask layer 320 and a resist layer 330 are formed on the light-transmitting substrate 300 in the main cell region A and the light-shielding layer 315 in the frame region B to form a blank mask. Herein, the mask layer 320 can be formed including a light-shielding layer in a case of a binary mask, a phase-shift layer and a light-shielding layer in a case of a phase-shift mask, and a mirror layer in a case of a mirror mask (extreme ultra violet).

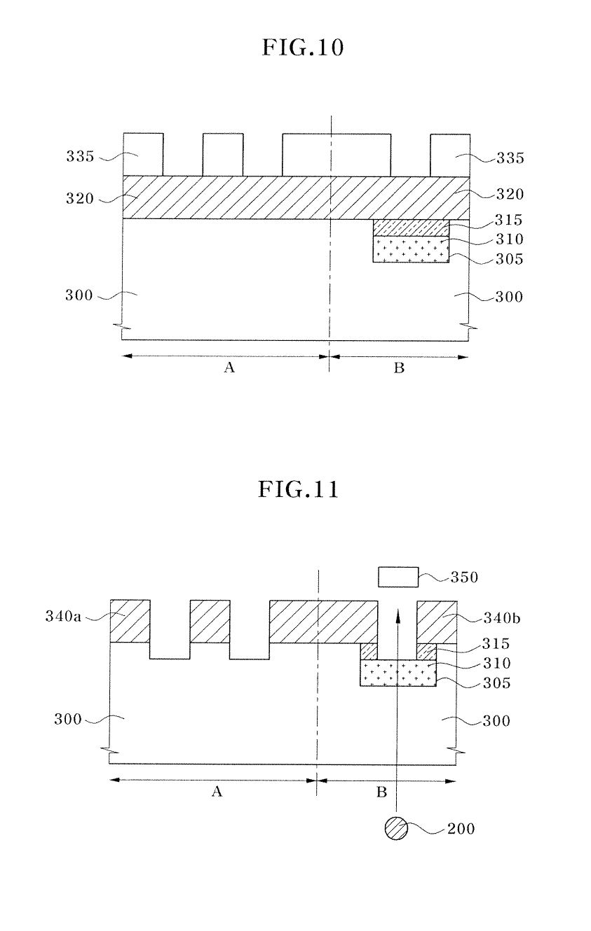

Referring to FIG. 10, a lithography process including an exposure process and the development process is performed on the resist layer (330 of FIG. 9) to form a resist pattern 335 that partially exposes a surface of the light-shielding layer 320.

Referring to FIG. 11, an etch process using the resist pattern 335 as an etch mask is performed to form a mask main pattern 340a in the main cell region A and a mask frame pattern 340b in the frame region B. When etching is performed on the patterns, the fluorescence is not generated if the etch is performed to the light-shielding layer 315 but a fluorescence intensity is rapidly increased if over-etch that can cause a mask defect is performed. Accordingly, it is possible to prevent generation of the over-etch by disposing a fluorometer 350 in a front side of the light-transmitting substrate 300 and monitoring the fluorescence intensity during the etch process is performed.

As such, it is possible to control an etch rate of the fluorescence layer and the mask layer by determining an etch degree of the mask layer from the fluorescence intensity of the fluorescence material residue according to the etch degree by comparing it with the reference fluorescence intensity, and it is possible to form a target pattern to be transferred on a wafer by controlling a relative variables for monitoring depending on a coating degree of the fluorescence layer (e.g. kinds of the fluorescence layer, deposition thickness, reduction rate, or transfer rate in the fluorescence upon over-etch).

Meanwhile, an etch process in a process for fabricating a photo mask is illustratively described as a preferred embodiment in the present disclosure, but the invention is not limited thereto. For example, the invention can be applied to a planarization process performed by chemical mechanical polishing. Also, when the fluorescence layer is uniformly formed in the main cell region, it can be utilized as a mask for monitoring an etch bias uniformity.

While the invention has been described with respect to the specific embodiments, various changes and modifications may be made without departing from the spirit and scope of the invention as defined in the following claims.

What is claimed is:

1. A method for fabricating a photo mask using a fluorescence layer, comprising:
forming a fluorescence layer on a frame region of a light-transmitting substrate that defines a main cell region and the frame region;
forming a phase-shift layer and a light-shielding layer on the light-transmitting substrate and the fluorescence layer;
forming a light-shielding main pattern in the main cell region and a light-shielding frame pattern in the frame region by patterning the light-shielding layer;
forming a phase-shift main pattern and a phase-shift frame pattern to expose a portion of a surface of the fluorescence layer on side walls thereof, by etching the phase-shift layer using the light-shielding main pattern and the light-shielding frame pattern as an etch mask;
irradiating light from a light source on the light-transmitting substrate and detecting an intensity of fluorescence of a fluorescence layer residue emitted from the exposed surface of the fluorescence layer; and
determining under-etch or over-etch using the detected fluorescence intensity as a reference fluorescence intensity.

2. The method of claim 1, wherein the fluorescence layer comprises a material having an excitation wavelength of 340 nm to 400 nm.

3. The method of claim 2, wherein the fluorescence layer contains fluorene or pyrene.

4. The method of claim 1, comprising detecting the fluorescence intensity by:
disposing a fluorometer in a front side of the light-transmitting substrate and a light source in a rear side of the light-transmitting substrate; and
irradiating light from the light source on the light-transmitting substrate and detecting the intensity of fluorescence of a fluorescence layer residue emitted from the fluorescence layer with the fluorometer.

5. The method of claim 1, comprising detecting the fluorescence intensity by irradiating ultraviolet light from an ultraviolet lamp on the light-transmitting substrate and inspecting the intensity of the emitted fluorescence with a user's eye.

6. The method of claim 1, comprising in determining the under-etch on the basis of the detected fluorescence intensity, determining etching of the phase-shift layer as the under-etch, wherein etching is performed only to a point not reaching a target etch point, when the intensity of the emitted fluorescence is higher than the reference fluorescence intensity.

7. The method of claim 1, comprising in determining the over-etch on the basis of the detected fluorescence intensity, determining etching of the phase-shift layer as the over-etch, wherein etching is performed only to a point not reaching a target etch point, when the intensity of the emitted fluorescence is lower than the reference fluorescence intensity or the intensity of fluorescence of a fluorescence layer residue is not detected.

8. A method for fabricating a photo mask using a fluorescence layer, comprising:
forming a trench in a frame region of a light-transmitting substrate that defines a main cell region and the frame region;
partially burying the trench with a fluorescence layer;
completely burying the trench by forming a light-shielding layer on the fluorescence layer;
forming a mask layer and a resist layer on the light-shielding layer and the light-transmitting substrate;
forming a resist pattern to expose a portion of a surface of the mask layer by patterning the resist layer; and
forming a mask main pattern in the main cell region and a mask frame region in the frame region by an etch process using the resist pattern as an etch mask, wherein the mask frame pattern is formed while restricting exposure of the fluorescence layer by monitoring an intensity of fluorescence in the frame region.

9. The method of claim 8, wherein the fluorescence layer comprises a material having an excitation wavelength of 340 nm to 400 nm.

10. The method of claim 8, wherein the fluorescence layer contains fluorene or pyrene.

11. The method of claim 8, comprising monitoring the fluorescence intensity by disposing a fluorometer in a front side of the light-transmitting substrate, setting up a point where the fluorescence intensity of the fluorescence layer is increased as an over-etch point, and monitoring the frame region.
